(19) United States
(12) Patent Application Publication
(10) Pub. No.: US 2024/0332455 A1
(43) Pub. Date: Oct. 3, 2024

(54) SEMICONDUCTOR STRUCTURE AND METHOD OF FORMING THE SAME

(71) Applicant: EPISTAR CORPORATION, Hsinchu (TW)

(72) Inventor: Min-Hsun HSIEH, Hsinchu (TW)

(21) Appl. No.: 18/608,092

(22) Filed: Mar. 18, 2024

(30) Foreign Application Priority Data
Mar. 28, 2023 (TW) 112111609

(51) Int. Cl. H01L 33/22; H01L 25/075; H01L 33/00

(52) U.S. Cl. CPC H01L 33/22; H01L 25/0753; H01L 33/0093

(57) ABSTRACT

The present application discloses a method of forming a semiconductor structure. The method of forming the semiconductor structure includes the following steps. A substrate is provided. An epitaxial structure with a patterned surface is formed on the substrate. The substrate is removed to expose the patterned surface of the epitaxial structure. A filling structure is formed over the patterned surface to form a flat surface. A singulation process is performed on the epitaxial structure to form a plurality of light emitting structures.

### CROSS-REFERENCE TO RELATED APPLICATION

This non-provisional application claims priority under 35 U.S.C. § 119 (a) to Patent Application No. 112111609 filed in Taiwan, R.O.C. on Mar. 28, 2023, the entire contents of which are hereby incorporated by reference.

### BACKGROUND

### Technical Field

The present application relates to a semiconductor structure and a method of forming the same, and in particular to a semiconductor structure for optical inspection and a method of forming the same.

### Related Art

Light-emitting diodes (LEDs) have been widely used in display devices. During the manufacturing process, light-emitting diodes are usually tested with a probe card. However, with the miniaturization of LEDs, the probe card is no longer suitable for testing micro LEDs because the size of the probe card is too large. Instead, non-contact inspection methods, such as photoluminescence (PL), have gradually been used in the testing process of micro LEDs. Nevertheless, the photoluminescence method is easily affected by the structure of the micro LED, which limits its application field. For example, the patterned surface of the LED can scatter light and interfere the measurement.

### SUMMARY

The present application discloses a method of forming a semiconductor structure. The method of forming the semiconductor structure includes the following steps. A substrate is provided. An epitaxial structure with a patterned surface is formed on the substrate. The substrate is removed to expose the patterned surface of the epitaxial structure. A filling structure is formed over the patterned surface to form a flat surface. A singulation process is performed on the epitaxial structure to form a plurality of light emitting structures.

In one embodiment, the semiconductor structure includes a carrier substrate and a plurality of light-emitting structures. The plurality of light-emitting structures is disposed on the carrier substrate. Each of the plurality of light-emitting structures includes a semiconductor base layer, a first type semiconductor layer, a light-emitting layer, a second type semiconductor layer and a filling structure. The semiconductor base layer has a patterned surface. The first type semiconductor layer is disposed on the surface opposite to the patterned surface. The light-emitting layer is disposed on the first type semiconductor layer. The second type semiconductor layer is disposed on the light-emitting layer. The filling structure is disposed on the patterned surface to convert the patterned surface into a flat surface.

### BRIEF DESCRIPTION OF THE DRAWINGS

FIGS. 1 to 6 are partial cross-section views in various stages of forming the semiconductor structure in accordance with one embodiment of the present disclosure.

FIG. 7 illustrates a top view of a semiconductor structure in accordance with one embodiment of the present disclosure.

FIG. 8 illustrates a partial cross-section view of a semiconductor structure in accordance with one embodiment of the present disclosure.

FIG. 9 illustrates a top view of a semiconductor structure in accordance with one embodiment of the present disclosure.

FIG. 10 is a partial cross-section view of a display panel according to some embodiments of the present disclosure.

### DETAILED DESCRIPTION

To make the objectives, features, and advantages of the embodiments of the present application more comprehensible, the following provides detailed descriptions with reference to the accompanying drawings.

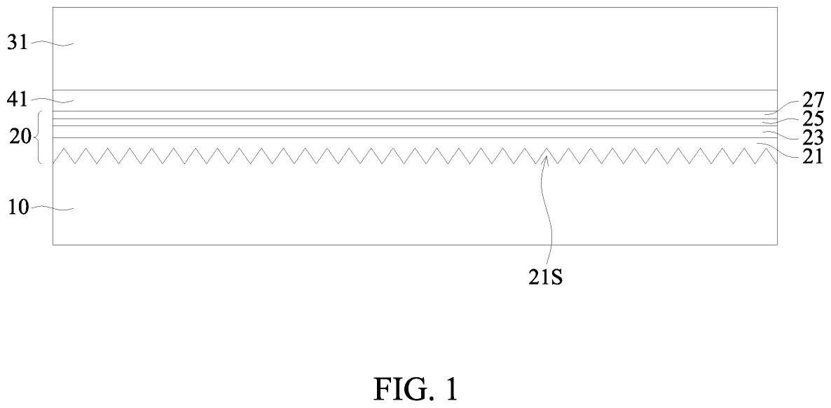

FIGS. 1 to 6 are partial cross-section views in various stages of forming a semiconductor structure in accordance with one embodiment of the present disclosure. It is important to note that some components of the semiconductor structure 100 have been omitted from FIGS. 1-6 for simplicity.

Referring to FIG. 1, in one embodiment, an epitaxial structure 20 is formed on a patterned substrate 10. The patterned substrate 10 may include sapphire, silicon carbide (SiC), or aluminum nitride (AlN). Alternatively, the patterned substrate 10 may include silicon, silicon germanium, gallium nitride, gallium arsenide, other suitable semiconductor materials, or combinations thereof, but the embodiment of the present disclosure is not limited thereto. The patterned substrate 10 can be a growth substrate for growing the epitaxial structure 20.

The epitaxial structure 20 can be formed on the patterned substrate 10 through epitaxial growth process. For example, the epitaxial growth process may include Metal Organic Chemical Vapor Deposition (MOCVD), Hydride Vapor Phase Epitaxy (HVPE), Molecular Beam Epitaxy (MBE), other applicable methods or combinations thereof, but the embodiment of the present disclosure is not limited thereto.

As shown in FIG. 1, in one embodiment, the epitaxial structure 20 includes a semiconductor base layer 21, a first type semiconductor layer 23, a light-emitting layer 25, and a second type semiconductor layer 27. The semiconductor base layer 21 includes gallium nitride (GaN) or aluminum nitride (AlN). In one embodiment, the semiconductor base layer 21 directly contacts the patterned substrate 10. Therefore, the semiconductor base layer 21 has a patterned surface 21S. As shown in FIG. 1, in one embodiment, the first type semiconductor layer 23 is disposed on a surface of the semiconductor base layer 21 opposite to the patterned surface 21S, and the light-emitting layer 25 is disposed on the first type semiconductor layer 23, and the second type semiconductor layer 27 is disposed on the light-emitting layer 25.

In one embodiment, the first type semiconductor layer 23 is an n type semiconductor layer. For example, the first type semiconductor layer 23 may include II-VI group materials (for example, ZnSc) or III-V nitrogen compound materials (for example, GaN, AlN, InN, InGaN, AlGaN or AlInGaN), and the first type semiconductor layer 23 may include other dopants, such as Si and Ge, but the embodiment of the disclosure is not limited thereto. In the embodiment of the disclosure, the first type semiconductor layer 23 may be a structure of a single layer or multiple layers.

In one embodiment, the light-emitting layer 25 may include an undoped semiconductor layer or a low doping concentration semiconductor layer, wherein the low doping concentration semiconductor layer has a doping concentration lower than 1*10¹⁸ cm⁻³, wherein the dopant is not limited to n type or p type dopants, such as Si, Ge, Mg, and C. For example, the light-emitting layer 25 may be a quantum well (QW) layer, which may include InGaN or GaN, but the embodiment of the present disclosure is not limited thereto. In other embodiments, the light-emitting layer 25 may also be a Multiple Quantum Well (MQW) layer.

In one embodiment, the second type semiconductor layer 27 is a p type semiconductor layer. For example, the second type semiconductor layer 27 may include II-VI group materials (for example, ZnSe) or III-V nitrogen compound materials (for example, GaN, AlN, InN, InGaN, AlGaN, and AlInGaN), and the second type semiconductor layer 27 may include Mg, C, or other dopants. In one embodiment, the second type semiconductor layer 27 may be a structure of single layer or multiple layers.

Referring to FIG. 1, in one embodiment, a first temporary substrate 31 is formed on the epitaxial structure 20. The first temporary substrate 31 may include transparent material (for example, sapphire). Furthermore, in one embodiment, a first glue layer 41 is formed between the epitaxial structure 20 and the first temporary substrate 31. The first glue layer 41 is able to adhere the epitaxial structure 20 and the first temporary substrate 31 to each other. For example, the first glue layer 41 may include benzocyclobutene (BCB), silicone resin (Silicone), epoxy resin (Epoxy), other suitable materials, or combinations thereof.

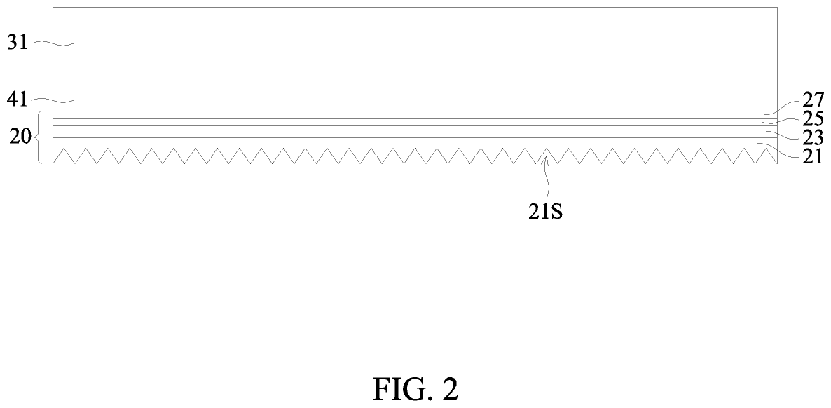

Referring to FIG. 2, in one embodiment, the patterned substrate 10 is removed to expose the patterned surface 21S of the epitaxial structure 20 (semiconductor base layer 21). In one embodiment, a laser lift-off (LLO) process can be used to separate the patterned substrate 10 from the epitaxial structure 20.

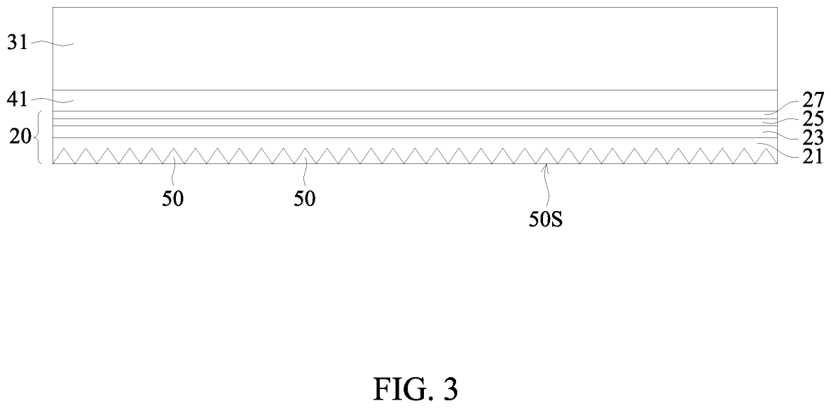

Referring to FIG. 3, in one embodiment, a filling structure 50 is formed over the patterned surface 21S of the epitaxial structure 20 (the semiconductor base layer 21) to form a flat surface 50S. In one embodiment, the filling structure 50 includes a material different from the semiconductor base layer 21, and the difference in the refractive index of the filling structure 50 and the refractive index of the semiconductor base layer 21 ranges from 0 to 0.5. In other words, the refractive index of the filling structure 50 is close to that of the semiconductor base layer 21. For example, for light with a wavelength of 450 to 660 nm, when the semiconductor base layer 21 includes GaN, the refractive index of the semiconductor base layer 21 is between 2.4 and 2.5. The filling structure 50 may include SiN, TiO₂, other suitable materials, or combinations thereof. For light with a wavelength of 450˜660 nm, the refractive index of the filling structure 50 may be substantially in the range of 2.1 to 2.4.

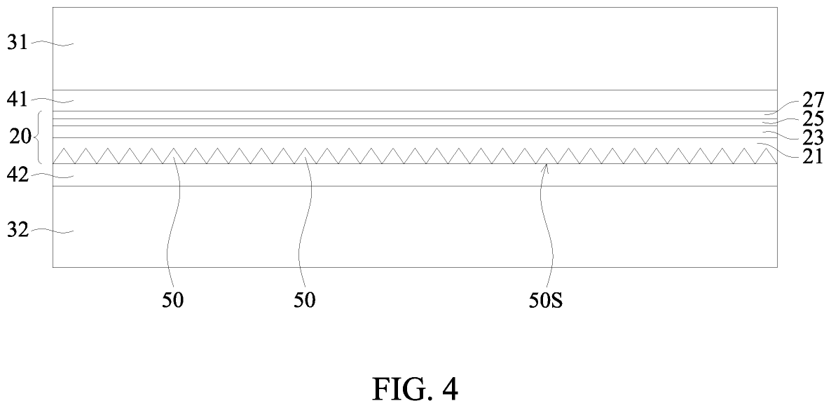

Referring to FIG. 4, in one embodiment, a second temporary substrate 32 is formed over the flat surface 50S. For example, the second temporary substrate 32 includes the same or similar material as the first temporary substrate 31. In one embodiment, a second glue layer 42 is formed between the flat surface 50S and the second temporary substrate 32. The second glue layer 42 is able to adhere the epitaxial structure 20 and the second temporary substrate 32 to each other. For example, the second glue layer 42 may include the same or similar material as the first glue layer 41.

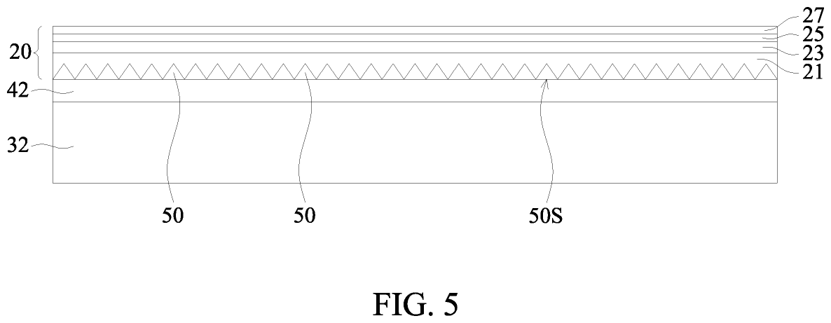

Referring to FIG. 5, in one embodiment, the first temporary substrate 31 is removed. For example, a laser lift-off process may be performed to separate the first temporary substrate 31 from the epitaxial structure 20.

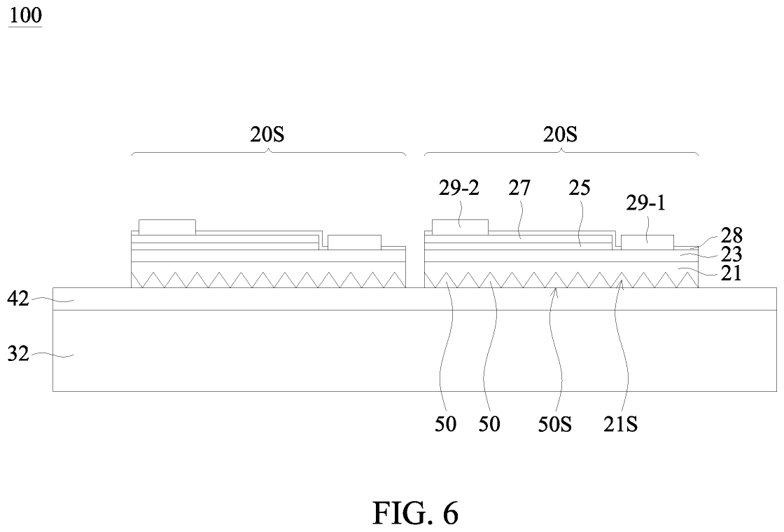

Referring to FIG. 6, in one embodiment, a singulation process is performed on the epitaxial structure 20 to form a plurality of light-emitting structures 20S. The singulation process may include performing a patterning process on the epitaxial structure 20 in FIG. 5. During the patterning process, the epitaxial structure 20 is covered by a mask layer (not shown) and a portion of the epitaxial structure 20 is etched away and to be separated into the plurality of light-emitting structures 20S. In addition, each of the plurality of light-emitting structures 20S further includes a first electrode 29-1 and a second electrode 29-2. The first electrode 29-1 and the second electrode 29-2 may be formed on the epitaxial structure 20 before or after the patterning process.

As shown in FIG. 6, in one embodiment, each of the plurality of light-emitting structure 20S includes a first electrode 29-1 and a second electrode 29-2. The first electrode 29-1 is electrically connected to the first type semiconductor layer 23, and the second electrode 29-2 is electrically connected to the second type semiconductor layer 27. The first electrode 29-1 and the second electrode 29-2 may include conductive materials, such as metal, metal oxide, and combinations thereof. The metal includes gold (Au), nickel (Ni), platinum (Pt), palladium (Pd), iridium (Ir), titanium (Ti), chromium (Cr), tungsten (W), aluminum (Al), copper (Cu), the aforementioned alloys or combinations of the aforementioned. The metal oxide includes indium tin oxide (ITO), indium zinc oxide (IZO), zinc oxide (ZnO), aluminum zinc oxide (AZO) or a combination of the above. For example, the first electrode 29-1 and the second electrode 29-2 can be formed through a deposition process and a patterning process, but the embodiment of the present disclosure is not limited thereto.

In addition, as shown in FIG. 6, in one embodiment, each of the plurality of light-emitting structures 20S further includes a reflective layer 28. The reflective layer 28 is disposed on the second type semiconductor layer 27 and part of the first type semiconductor layer 23. For example, the reflective layer 28 may include a distributed Bragg reflector (DBR), which may be composed of multiple layers of materials with different refractive indexes. Specifically, the reflective layer 28 can be formed through a deposition process, and through holes can be formed in the reflective layer 28 through a patterning process, so that the first electrode 29-1 can pass through the reflective layer 28 to be electrically connected to the first type semiconductor layer 23, and the second electrode 29-2 can pass through the reflective layer 28 to be electrically connected to the second type semiconductor layer 27, but the embodiment of the present disclosure is not limited thereto.

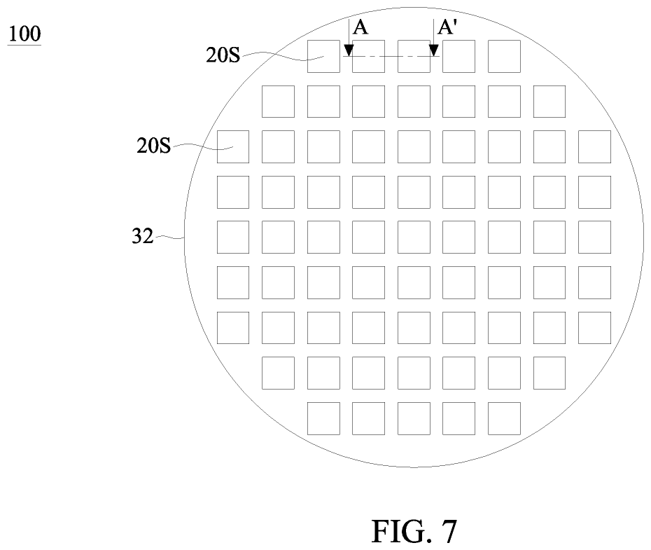

FIG. 7 illustrates a top view of a semiconductor structure 100 according to one embodiment of the present disclosure. The semiconductor structure 100 shown in FIG. 6 may be a partial cross-section view along line A-A′ in FIG. 7, but the embodiment of the present disclosure is not limited thereto. It should be noted that the number of light-emitting structures 20S shown in FIG. 7 is only for illustration, and the actual number of light-emitting structures 20S may be greater or smaller than that shown in FIG. 7.

Referring to FIG. 6, when the luminescence characteristics of the light-emitting structure 20S in the semiconductor structure 100 is inspected, a photoluminescence (Photoluminescence) inspection device can be used. The photoluminescence inspection device can emit a light beam (for example, laser light with a wavelength of 266 nm) through the second temporary substrate 32 and excite the active region (light-emitting layer 25) of the light-emitting structure 20S to emit light. The photoluminescence method is not necessary to contact the light-emitting structure 20S physically, so it can be adapted to the light-emitting structures 20S which is small and perform faster and larger amounts of inspection.

The semiconductor structure 100 includes a filling structure 50. The filling structure 50 can be filled into the patterned surface 21S of the epitaxial structure 20 (the semiconductor base layer 21) and form a flat surface 50S. The flat surface 50S and the second glue layer 42 can be adhered to each other more closely without gaps between thereof. Since the difference in refractive index between the filling structure 50 and the semiconductor base layer 21 is less than 0.5, compared with the patterned surface 21S, the light beam is less likely to be scattered on the flat surface 50S, and a larger proportion of the light beam can enter the active area (light-emitting layer 25) for exciting stronger light, thereby improving inspection accuracy.

In one embodiment, the filling structure 50 is filled on the patterned surface 21S of the epitaxial structure 20 (semiconductor base layer 21) before the separation process to form a flat surface 50S. In another embodiment, the filling structure 50 is filled on the patterned surface 21S of the epitaxial structure 20 (semiconductor base layer 21) after the separation process to form a flat surface 50S.

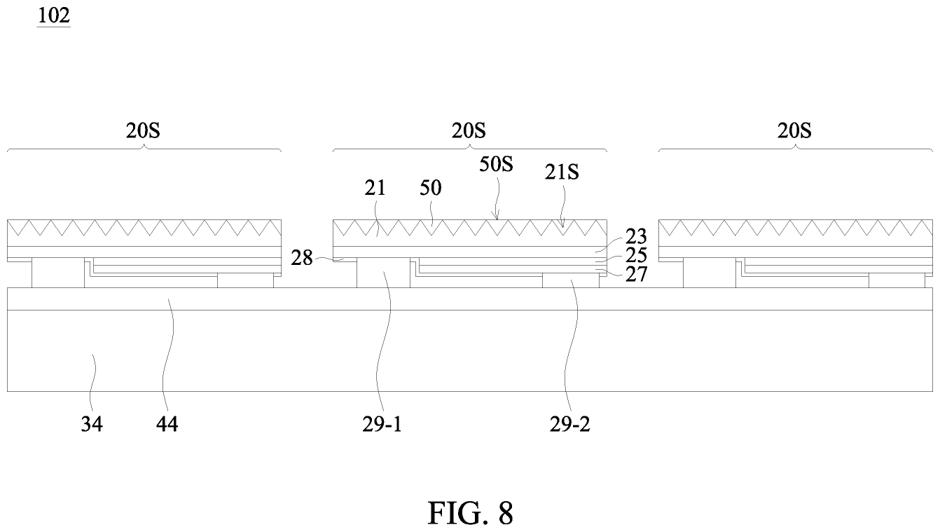

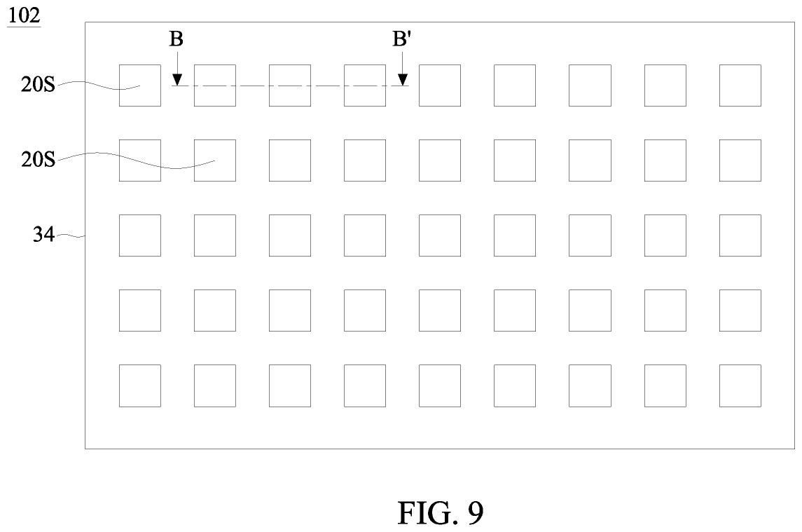

FIG. 8 illustrates a partial cross-section view of a semiconductor structure 102 according to one embodiment. FIG. 9 illustrates a top view of a semiconductor structure 102 in accordance with one embodiment. In one embodiment, the semiconductor structure 102 shown in FIG. 8 is a cross-section view taken along line B-B′ in FIG. 9. The number of light-emitting structures 20S shown in FIG. 9 is only for illustration, and the actual number of light-emitting structures 20S may be greater or smaller than the number of light-emitting structures 20S shown in FIG. 9.

The semiconductor structure 102 shown in FIGS. 8 and 9 can be regarded as the result of another transfer process for the semiconductor structure 100 shown in FIGS. 6 and 7. That is, the plurality of light-emitting structures 20S of the semiconductor structure 100 is transferred to the carrier substrate 34 and form the semiconductor structure 102. The material of the carrier substrate 34 may include materials with sufficient rigidity like silicon, glass, sapphire, silicon carbide, or combinations thereof.

As shown in FIG. 8, the light-emitting structures 20S in FIG. 6 are transferred and placed upside down on the carrier substrate 34. Namely, the first electrode 29-1 and the second electrode 29-2 of each of the light-emitting structures 20S are facing the carrier substrate 34. In another embodiment (not shown), the light-emitting structures 20S in FIG. 6 are transferred to the carrying substrate 34 and still maintains their orientation on the second temporary substrate 32. Namely, the flat surface 50S of each of the light-emitting structures 20S faces the carrying base 34.

As shown in FIG. 8, the semiconductor structure 102 includes a glue layer 44. The glue layer 44 is disposed between the carrier substrate 34 and the plurality of light-emitting structures 20S, and can fix the plurality of light-emitting structures 20S on the carrier substrate 34. For example, the glue layer 44 may include a heat-removable tape, a photoremovable adhesive film, a chemical-removable tape, a heat-resistant tape, a blue film, a tape with a dynamic release layer, or a combination thereof.

In the semiconductor structure 102 shown in FIG. 9, the distance between any two of the adjacent light-emitting structures 20S can be adjusted according to subsequent process requirements, which can be the same as or different from the distance between any two of the adjacent light-emitting structures 20S in the semiconductor structure 100 shown in FIG. 7.

Referring to FIG. 8, similarly, when the plurality of light-emitting structures 20S in the semiconductor structure 102 is to be inspected at one time, photoluminescence inspection device can be used. The photoluminescence inspection device can emit light beams (for example, laser light with a wavelength of 266 nm) into each of the plurality of light-emitting structures 20S from the flat surface 50S thereof and excite the active region (light-emitting layer 25) thereof to emit light.

Since the patterned surface 21S of each of the plurality of light-emitting structures 20S is filled with the filling structure 50 to form a flat surface 50S, and the refractive index difference between the filling structure 50 and the semiconductor base layer 21 is less than 0.5, when the light beam emitted by the inspection device enters the active region (light-emitting layer 25) from the outside, the scattering that originally occurred on the patterned surface 21S can be eliminated or reduced, and a larger proportion of the light beam can enter the active region, thereby exciting stronger light, and the measurement accuracy of the inspection device can also be improved.

Referring to FIGS. 6 and 8, in one embodiment, the semiconductor structure (for example, 100 or 102) includes a carrier (for example, the second temporary substrate 32 or the carrier substrate 34) and a plurality of light emitting structures 20S. The plurality of light-emitting structures 20S is disposed on the carrier. Each of the plurality of light-emitting structures 20S includes a semiconductor base layer 21, a first type semiconductor layer 23, a light-emitting layer 25, a second type semiconductor layer 27 and a filling structure 50. The semiconductor base layer 21 has a patterned surface 21S. The first type semiconductor layer 23 is disposed on one surface of the semiconductor base layer 21 opposite to the patterned surface 21S. The light-emitting layer 25 is disposed on the first type semiconductor layer 23. The second type semiconductor layer 27 is disposed on the light emitting layer 25. The filling structure 50 is disposed on the patterned surface 21S to transform the patterned surface 21S into a flat surface 50S.

In addition, in one embodiment, the light-emitting structure 20S further includes a first electrode 29-1 and a second electrode 29-2. The first electrode 29-1 is electrically connected to the first type semiconductor layer 23, and the electrode 29-2 is electrically connected to the second type semiconductor layer 27.

As shown in FIG. 6, the filling structure 50 is located between the semiconductor base layer 21 and the carrier (i.e., the second temporary substrate 32). As shown in FIG. 8, the first electrode 29-1 and the second electrode 29-2 are located between the semiconductor base layer 21 and the carrier (i.e., the carrier substrate 34), or the first electrode 29-1 and the second electrode 29-2 are located between the filling structure 50 and the carrier (i.e., the carrier substrate 34).

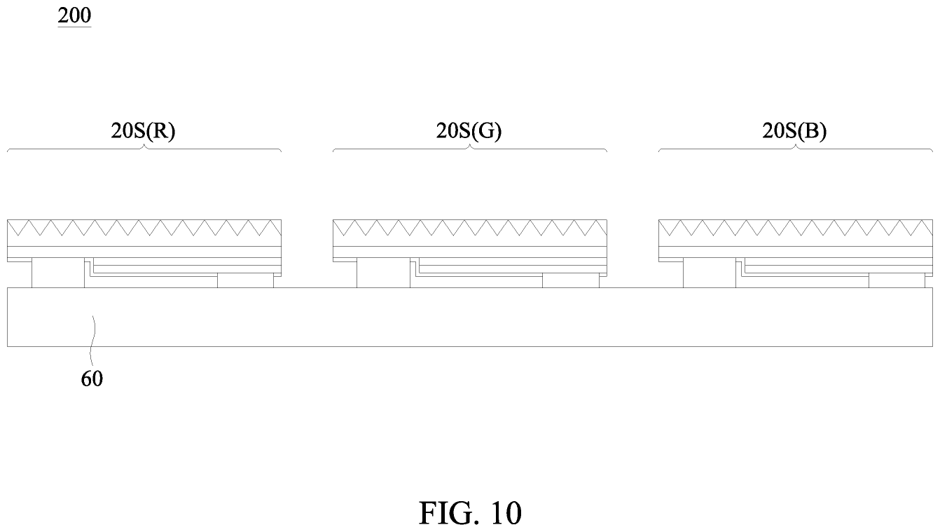

FIG. 10 illustrates a partial cross-section view of a display panel 200 in accordance with one embodiment of the present disclosure. The plurality of light emitting structures 20S of the semiconductor structure 100 of the semiconductor structure 102 is transferred to a display backplane 60 to form the display panel 200. The display backplane 60 may be a rigid or flexible structure, and the display backplane 60 may be a single-layer or multi-layer structure. The display backplane 60 includes a printed circuit board (PCB), a transparent circuit board, or a flexible circuit board. The printed circuit board includes ABF (Ajinomoto Build-up Film) carrier board, BT (Bismaleimide Triazine) carrier board, or HDI carrier board. The transparent circuit board includes a transparent carrier board and a circuit formed on the transparent carrier board, wherein the transparent carrier board includes glass, quartz, sapphire, or other suitable hard transparent materials. The flexible circuit board includes flexible material and circuits formed on the flexible material. The flexible material includes insulating material, or conductive material. The insulating material includes polyimide (PI), polyterephthalene Polyethylene Terephthalate (PET), or Poly Methyl Methacrylate (PMMA). The conductive material includes copper, iron, titanium, magnesium, or alloys of the above materials. When the flexible material is a conductive material, an insulating layer needs to be formed between the circuit and the conductive material.

The light-emitting structure 20S can be a light-emitting diode (Light-Emitting diode; LED) that can emit red, blue, or green light. In other embodiments, the light-emitting structure 20S is a light-emitting diode that can emit cyan light, infrared (IR) light, or ultraviolet (UV) light.

Following the above description, the filling structure can be formed on the patterned surface of the semiconductor structure through the forming method of the embodiment of the present disclosure. The filling structure can convert the patterned surface into a flat surface, thereby reducing the scattering of the light emitted by the inspection device, which makes the light-emitting structure (for example, a micro light-emitting diode) in the semiconductor structure is easy to be inspected, thereby improving the inspection accuracy.

Although the present application has been described in considerable detail with reference to certain preferred embodiments thereof, the disclosure is not for limiting the scope of the application. Persons having ordinary skill in the art may make various modifications and changes without departing from the scope and spirit of the present application. Therefore, the scope of the appended claims should not be limited to the description of the preferred embodiments described above.

What is claimed is:

1. A method of forming a semiconductor structure, comprising:
providing a substrate;
forming an epitaxial structure with a patterned surface on the substrate;
removing the substrate to expose the patterned surface of the epitaxial structure;
forming a filling structure on the patterned surface to form a flat surface; and
performing a singulation process on the epitaxial structure to form a plurality of light-emitting structures.

2. The method of forming the semiconductor structure according to claim 1, further comprising forming a first temporary substrate on the epitaxial structure after forming the epitaxial structure.

3. The method for forming the semiconductor structure according to claim 2, further comprising forming a first glue layer between the epitaxial structure and the first temporary substrate.

4. The method of forming the semiconductor structure according to claim 2, further comprising:
forming a second temporary substrate on the flat surface; and
removing the first temporary substrate after the flat surface is formed.

5. The method of forming the semiconductor structure according to claim 2, further comprising forming a second glue layer between the flat surface and the second temporary substrate.

6. The method of forming the semiconductor structure according to claim 1, wherein a laser lift-off process is performed for removing the substrate.

7. The method of forming the semiconductor structure according to claim 1, wherein the epitaxial structure includes:
a semiconductor base layer having the patterned surface;
a first type semiconductor layer is disposed on a surface opposite to the patterned surface;
a light-emitting layer disposed on the first type semiconductor layer; and
a second type semiconductor layer is disposed on the light-emitting layer.

8. The method of forming the semiconductor structure according to claim 1, wherein forming the filling structure on the patterned surface is performed after forming the light-emitting structures.

9. The method of forming the semiconductor structure according to claim 1, wherein the substrate comprises a sapphire, SiC, or AlN.

10. A semiconductor structure, comprising:
a carrier substrate; and
a plurality of light-emitting structures is provided on the carrier substrate, wherein each of the plurality of light-emitting structures comprises:
a semiconductor base layer having a patterned surface and a surface opposite to the patterned surface;
a first type semiconductor layer disposed on the surface;
a light-emitting layer disposed on the first type semiconductor layer;
a second type semiconductor layer disposed on the light-emitting layer; and
a filling structure is disposed on the patterned surface to form a flat surface.

11. The semiconductor structure according to claim 10, wherein the filling structure comprises a material different from that of the semiconductor base layer, and a refractive index difference between the filling structure and the semiconductor base layer is less than 0.5.

12. The semiconductor structure according to claim 10, wherein each of the plurality of light-emitting structures further comprises:
a first electrode being electrically connected to the first type semiconductor layer; and
a second electrode being electrically connected to the second type semiconductor layer.

13. The semiconductor structure according to claim 12, wherein the filling structure is disposed between the semiconductor base layer and the carrier substrate.

14. The semiconductor structure according to claim 12, wherein the first electrode and the second electrode are disposed between the semiconductor base layer and the carrier substrate.

15. The semiconductor structure according to claim 10, wherein the carrier substrate comprises silicon, sapphire, and silicon carbide.

16. The semiconductor structure according to claim 10, further comprising a glue layer disposed between the carrier substrate and the plurality of light-emitting structures.

17. The semiconductor structure of claim 16, wherein the glue layer comprises a thermal removable tape, a photoremovable adhesive film, a chemical removable tape, a heat-resistant tape, a blue film, or a tape with a dynamic release layer.
